(19) United States
(12) Patent Application Publication
(10) Pub. No.: US 2016/0380239 A1
(43) Pub. Date: Dec. 29, 2016

(54) METHOD FOR MANUFACTURING AMOLED DISPLAY DEVICE AND STRUCTURE THEREOF

(71) Applicant: SHENZHEN CHINA STAR OPTOELECTRONICS TECHNOLOGY CO. LTD., Shenzhen City (CN)

(72) Inventor: Xiangyang XU, Shenzhen City (CN)

(21) Appl. No.: 14/777,741

(22) PCT Filed: Jul. 23, 2015
(86) PCT No.: PCT/CN2015/084866

§ 371 Date: Sep. 16, 2015

(30) Foreign Application Priority Data
Jun. 26, 2015 (CN) 201510366825.X

(51) Int. Cl. H01L 51/52; H01L 27/32; H01L 27/12

(52) U.S. Cl. CPC H01L 51/5281; H01L 27/1262; H01L 27/3262; H01L 2227/323; H01L 2251/303

(57) ABSTRACT

The present invention provides a method for manufacturing an AMOLED display device and a structure thereof. The method for manufacturing the AMOLED display device includes, before formation of a gate electrode (3), first depositing and subjecting an inorganic film a plasma bombardment treatment to form a gate reflection prevention layer (2) and, before formation of source/drain electrodes (71) and a data line (72), first depositing and subjecting an inorganic film to a plasma bombardment treatment to form an etching stop and source/drain reflection prevention layer (6), so as to provide the AMOLED display device with an excellent effect of preventing reflection of external surrounding light, increase display brightness of the AMOLED display device, extend the lifespan of the AMOLED display device, and reduce the thickness and manufacturing cost of the AMOLED display device. The structure of the AMOLED display device includes a gate metal reflection prevention layer (2) and an etching stop and source/drain reflection prevention layer (6) so as to achieve an excellent effect of preventing reflection of external surrounding light, increased display brightness, extended lifespan, a reduced thickness, and a lowered manufacturing cost.

### BACKGROUND OF THE INVENTION

1. Field of the Invention

The present invention relates to the field of display technology, and in particular to a method for manufacturing an active matrix organic light-emitting diode (AMOLED) display device and a structure thereof.

2. The Related Arts

An organic light emitting diode (OLED) display device has various advantages, including being self-luminous, low driving voltage, high luminous efficiency, short response time, high resolution and contrast, approximately 180 degree view angle, wide operation temperature range, and being capable of flexible displaying and large-area full-color displaying, and is thus considered a display device having the most prosperous future.

The OLED display devices can be classified as two types, which are passive matrix OLED (PMOLED) and active matrix OLED (AMOLED), according to how it is driven. The AMOLED comprises pixels arranged in an array and is a type that actively displays, having high luminous efficiency, and is commonly used in high-definition large-sized display devices.

The AMOLED is a thin-film luminous device driven by DC voltages. The AMOLED display technology is different from the traditional LCD display techniques by requiring no backlighting and is formed of extremely thin organic material coating layers and glass substrates. When an electrical current flows therethrough, the organic materials emit light. In addition, the AMOLED display device can be made thinner and lighter with an expanded view angle, and allows for significant saving of electrical power.

As shown in FIG. 1, a conventional AMOLED display device generally comprises, from bottom to top, a glass substrate 100, a thin-film transistor (TFT) array layer 200, a pixel electrode layer 300, which is an anode layer, an organic light emission layer 400, a cathode layer 500, and a package lid 600. The TFT array layer 200 comprises therein gate electrodes, data lines, and source/drain electrodes, which are all metal layers. Metals have strong power of reflecting light. In addition, the anode layer 300 and the cathode layer 500 that are respectively located on upper and lower sides of the organic light emission layer 400 are generally formed of light-reflective materials or semi-light-reflective materials. Further, the area of the AMOLED display device that corresponds to the organic light emission layer 400 is an open area, allowing external light to enter the AMOLED display device and induce strong reflection thereby affecting the displaying performance of the AMOLED display device. Heretofore, a solution that is commonly adopted to overcome the light reflection issue of an AMOLED display device is to attach a circular polarization sheet to the glass substrate 100 or the package lid 600. FIG. 1 schematically illustrates a circular polarization sheet 700 is attached to an undersurface of the glass substrate 100 so that the circular polarization sheet 700 may provide an effect of preventing reflection. However, a negative effect of attaching the circular polarization sheet is that the display brightness of the OLED display device would be significantly reduced. To provide the OLED display device with the same display brightness as that before the sheet is attached, the consumption of power must be increased. The increased power consumption in turn greatly shortens the lifespan of the AMOLED display device and the overall thickness of the AMOLED display device is also increased by around 160 μm or even more. In addition, adding the circular polarization sheet also raises the manufacturing cost of the AMOLED display device.

### SUMMARY OF THE INVENTION

An object of the present invention is to provide a method for manufacturing an active matrix organic light emitting diode (AMOLED) display device, which provides the AMOLED display device with an excellent effect of preventing reflection of external surrounding light without adding a circular polarization sheet so as to increase the display brightness of the AMOLED display device, extend the lifespan of the AMOLED display device, and reduce the thickness and manufacturing cost of the AMOLED display device.

Another object of the present invention is to provide a structure of an AMOLED display device, which has an excellent effect of preventing reflection of external surrounding light and has increased display brightness and extended lifespan and has a reduced thickness and lowered manufacturing cost.

To achieve the above objects, the present invention provides a method for manufacturing an AMOLED display device, which comprises:

a step of first depositing an inorganic film before making a gate electrode and then obtaining a rough surface of the inorganic film by a plasma bombardment treatment to form a gate reflection prevention layer; and

a step of first depositing an inorganic film before making source/drain electrodes and a data line, and then obtaining a rough surface of the inorganic film by a plasma bombardment treatment to form an etching stop and source/drain reflection prevention layer.

The method for manufacturing the AMOLED display device comprises the following steps:

(1) providing a substrate, depositing an inorganic film on the substrate, and subjecting the inorganic film to a plasma bombardment treatment to have a surface thereof roughened to form a gate reflection prevention layer;

(2) depositing a first metal layer on the gate reflection prevention layer and patterning the first metal layer to form a gate electrode;

(3) depositing a gate insulation layer on the gate electrode and the gate reflection prevention layer;

(4) depositing a semiconductor film on the gate insulation layer and patterning the semiconductor film to form an island-like active layer;

(5) depositing an inorganic film on the island-like active layer and the gate insulation layer, subjecting the inorganic film to a plasma bombardment treatment to have a surface thereof roughened to form an etching stop and source/drain reflection prevention layer, and then patterning the etching stop and source/drain reflection prevention layer to form a first via and a second via, the first via and the second via respectively exposing two opposite side portions of the island-like active layer;

(6) depositing a second metal layer on the etching stop and source/drain reflection prevention layer, and then patterning the second metal layer to form source/drain electrodes and a data line, wherein the source/drain electrodes are respectively connected by the first via and the second via to the island-like active layer;

(7) depositing a passivation protection layer on the source/drain electrodes, the data line, the etching stop and source/drain reflection prevention layer, and then patterning the passivation protection layer to form a third via, the third via exposing a portion of the source/drain electrodes;

(8) depositing a transparent electrode layer on the passivation protection layer, and then patterning the transparent electrode layer to form a pixel electrode layer, wherein the pixel electrode layer is connected by the third via to a portion of the source/drain electrodes;

(9) depositing a pixel separation layer on the pixel electrode layer and the passivation protection layer and patterning the pixel separation layer to form an opening that exposes a portion of the pixel electrode layer;

(10) applying a vapor deposition operation to form an organic light emission layer in the opening;

(11) sputtering a metallic cathode layer on the organic light emission layer and the pixel separation layer; and

(12) packaging with a package lid.

The inorganic film of step (1) is formed of a material of silicon dioxide, and the inorganic film has a thickness of 1000-3000 Å;

The first metal layer of step (2) is formed of a material of one of chromium, molybdenum, aluminum, and copper or a combination of multiple ones thereof, and the first metal layer has a thickness of 1000-6000 Å.

The gate insulation layer of step (3) is formed of a material of silicon oxide, silicon nitride, or a combination thereof, and the gate insulation layer has a thickness of 2000-5000 Å.

The semiconductor film of step (4) is formed of a material of one of zinc oxide, indium zinc oxide, zinc tin oxide, gallium indium zinc oxide, and zirconium indium zinc oxide, and the semiconductor film has a thickness of 200-2000 Å.

The inorganic film of step (5) is formed of a material of silicon oxide, and the inorganic film has a thickness of 500-2000 Å.

The plasma bombardment treatments of step (1) and step (5) use a gas of nitrogen, oxygen, or nitrogen dioxide.

The second metal layer of step (6) is formed of a material of one of chromium, molybdenum, aluminum, and copper or a combination of multiple ones thereof, and the second metal layer has a thickness of 1000-6000 Å.

The passivation protection layer of step (7) is formed of a material of silicon oxide, silicon nitride, or a combination thereof, and the passivation protection layer has a thickness of 2000-4000 Å.

The transparent electrode layer of step (8) is formed of a material of indium tin oxide or indium zinc oxide, and the transparent electrode layer has a thickness of 100-1000 Å;

The pixel separation layer of step (9) is formed of a material of silicon oxide, and the pixel separation layer has a thickness of 500-2000 Å;

The organic light emission layer of step (10) comprises a hole injection layer, a hole transport layer, an emissive layer, an electron transport layer, and an electron injection layer.

The present invention also provides a structure of an AMOLED display device, which comprises an array substrate and a passivation protection layer, a pixel electrode layer, a pixel separation layer, an organic light emission layer, a metallic cathode layer, and a package lid that are arranged, in sequence from bottom to top, on the array substrate;

the array substrate comprising a gate metal reflection prevention layer that has a roughened surface and is arranged under a gate electrode and an etching stop and source/drain reflection prevention layer that has a roughened surface, and the gate metal reflection prevention layer is arranged under source/drain electrodes and a data line.

The array substrate comprises a substrate, the gate reflection prevention layer arranged on the substrate, the gate electrode arranged on the gate reflection prevention layer, a gate insulation layer arranged on the gate electrode and the gate reflection prevention layer, an island-like active layer arranged on the gate insulation layer and located above the gate electrode, the etching stop and source/drain reflection prevention layer arranged on the island-like active layer and the gate insulation layer, and the source/drain electrodes and the data line arranged on the etching stop and source/drain reflection prevention layer; the etching stop and source/drain reflection prevention layer comprises a first via and a second via that respectively expose two opposite side portions of the island-like active layer; and the source/drain electrodes are respectively connected by the first via and the second via to the island-like active layer;

the passivation protection layer is arranged on the source/drain electrodes, the data line and the etching stop, and source/drain reflection prevention layer and comprises a third via, the third via exposing a portion of the source/drain electrodes;

the pixel electrode layer is arranged on the passivation protection layer and is connected by the third via to a portion of the source/drain electrodes;

the pixel separation layer is arranged on the pixel electrode layer and comprises an opening that exposes a portion of the pixel electrode layer;

the organic light emission layer is arranged in the opening of the pixel electrode layer; and

the metallic cathode layer is arranged on the organic light emission layer and the pixel separation layer.

The gate metal reflection prevention layer is formed of a material of silicon dioxide, and the gate metal reflection prevention layer has a thickness of 1000-3000 Å.

The etching stop and source/drain reflection prevention layer is formed of a material of silicon oxide, and the etching stop and source/drain reflection prevention layer has a thickness of 500-2000 Å.

The present invention further provides a structure of an AMOLED display device, which comprises an array substrate and a passivation protection layer, a pixel electrode layer, a pixel separation layer, an organic light emission layer, a metallic cathode layer, and a package lid that are arranged, in sequence from bottom to top, on the array substrate;

the array substrate comprising a gate metal reflection prevention layer that has a roughened surface and is arranged under a gate electrode and an etching stop and source/drain reflection prevention layer that has a roughened surface and is arranged under source/drain electrodes and a data line;

wherein the array substrate comprises a substrate, the gate reflection prevention layer arranged on the substrate, the gate electrode arranged on the gate reflection prevention layer, a gate insulation layer arranged on the gate electrode and the gate reflection prevention layer, an island-like active layer arranged on the gate insulation layer and located above the gate electrode, the etching stop and source/drain reflection prevention layer arranged on the island-like active layer and the gate insulation layer, and the source/drain electrodes and the data line arranged on the etching stop and source/drain reflection prevention layer; the etching stop and source/drain reflection prevention layer comprises a first via and a second via that respectively expose two opposite side portions of the island-like active layer; and the source/drain electrodes are respectively connected by the first via and the second via to the island-like active layer;

the passivation protection layer is arranged on the source/drain electrodes, the data line and the etching stop, and source/drain reflection prevention layer and comprises a third via, the third via exposing a portion of the source/drain electrodes;

the pixel electrode layer is arranged on the passivation protection layer and is connected by the third via to a portion of the source/drain electrodes;

the pixel separation layer is arranged on the pixel electrode layer and comprises an opening that exposes a portion of the pixel electrode layer;

the organic light emission layer is arranged in the opening of the pixel electrode layer; and

the metallic cathode layer is arranged on the organic light emission layer and the pixel separation layer;

wherein the gate metal reflection prevention layer is formed of a material of silicon dioxide, and the gate metal reflection prevention layer has a thickness of 1000-3000 Å; and

wherein the etching stop and source/drain reflection prevention layer is formed of a material of silicon oxide, and the etching stop and source/drain reflection prevention layer has a thickness of 500-2000 Å.

The efficacy of the present invention is that the present invention provides a method for manufacturing an AMOLED display device, wherein before a gate electrode is formed, an inorganic film is first formed and the inorganic film is subjected to a plasma bombardment treatment to have a surface thereof roughened to form a gate reflection prevention layer and wherein before source/drain electrodes and a data line are formed, an inorganic film is first formed and the inorganic film is subjected to a plasma bombardment treatment to have a surface thereof roughened to form an etching stop and source/drain reflection prevention layer, whereby the AMOLED display device is provided with an excellent effect of preventing reflection of external surrounding light without adding a circular polarization sheet so as to increase the display brightness of the AMOLED display device, extend the lifespan of the AMOLED display device, and reduce the thickness and manufacturing cost of the AMOLED display device. The present invention provides a structure of an AMOLED display device, which comprises an array substrate that is provided with a surface-roughened gate metal reflection prevention layer located under a gate electrode and a surface-roughened etching stop and source/drain reflection prevention layer that is located under source/drain electrodes and a data line so as to have an excellent effect of preventing reflection of external surrounding light and have increased display brightness, extended lifespan, a reduced thickness, and a lowered manufacturing cost.

For better understanding of the features and technical contents of the present invention, reference will be made to the following detailed description of the present invention and the attached drawings. However, the drawings are provided for the purposes of reference and illustration and are not intended to impose limitations to the present invention.

### BRIEF DESCRIPTION OF THE DRAWINGS

The technical solution, as well as other beneficial advantages, of the present invention will be apparent from the following detailed description of embodiments of the present invention, with reference to the attached drawing. In the drawing,

FIG. 1 is a schematic view showing a conventional active matrix organic light emitting diode (AMOLED) display device;

FIG. 2 is a flow chart illustrating a method for manufacturing an AMOLED display device according to the present invention;

FIG. 3 is a schematic view illustrating a first step of the method for manufacturing the AMOLED display device according to the present invention;

FIG. 4 is a schematic view illustrating a second step of the method for manufacturing the AMOLED display device according to the present invention;

FIG. 5 is a schematic view illustrating a third step of the method for manufacturing the AMOLED display device according to the present invention;

FIG. 6 is a schematic view illustrating a fourth step of the method for manufacturing the AMOLED display device according to the present invention;

FIG. 7 is a schematic view illustrating a fifth step of the method for manufacturing the AMOLED display device according to the present invention;

FIG. 8 is a schematic view illustrating a sixth step of the method for manufacturing the AMOLED display device according to the present invention;

FIG. 9 is a schematic view illustrating a seventh step of the method for manufacturing the AMOLED display device according to the present invention;

FIG. 10 is a schematic view illustrating an eighth step of the method for manufacturing the AMOLED display device according to the present invention;

FIG. 11 is a schematic view illustrating a ninth step of the method for manufacturing the AMOLED display device according to the present invention;

FIG. 12 is a schematic view illustrating a tenth step of the method for manufacturing the AMOLED display device according to the present invention;

FIG. 13 is a schematic view illustrating an eleventh step of the method for manufacturing the AMOLED display device according to the present invention; and

FIG. 14 is a schematic view illustrating a twelfth step of the method for manufacturing the AMOLED display device according to the present invention and is also a schematic view showing the structure of an AMOLED display device according to the present invention.

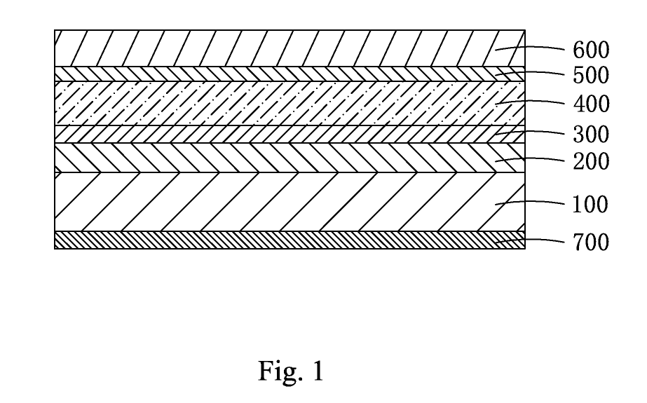

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

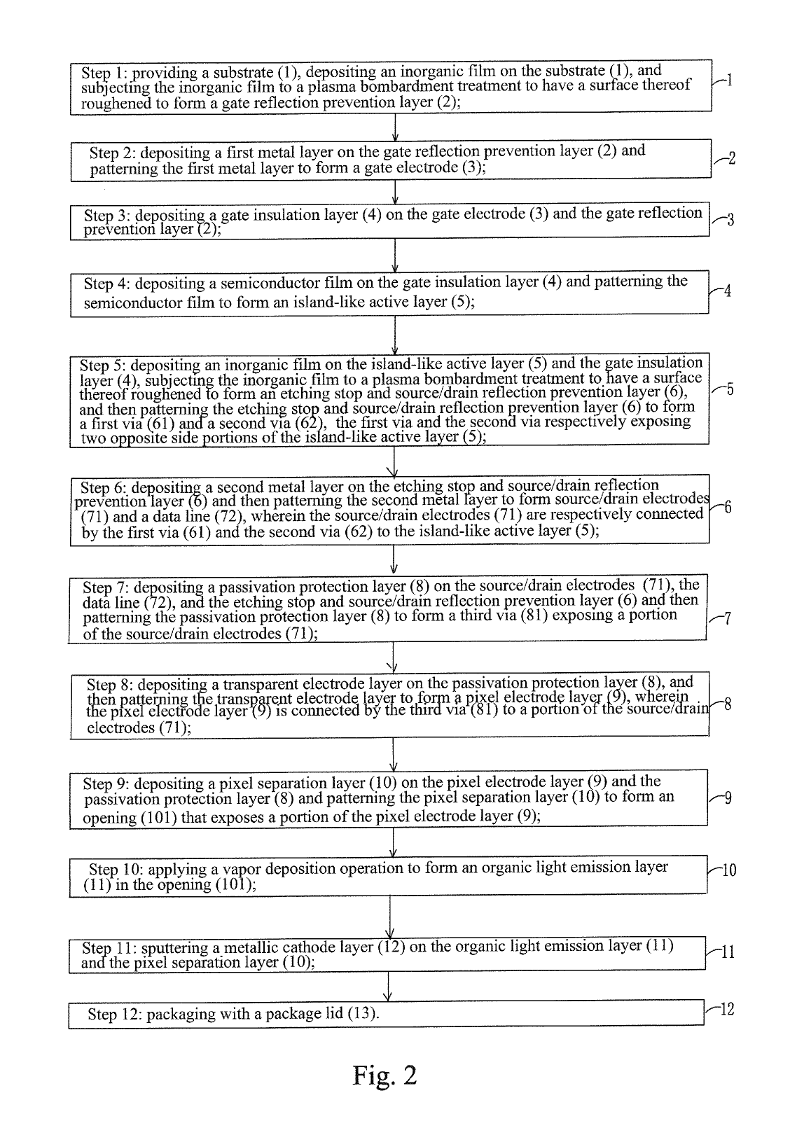

Referring to FIG. 2, firstly, the present invention provides a method for manufacturing an active matrix organic light emitting diode (AMOLED) display device, comprising the following steps:

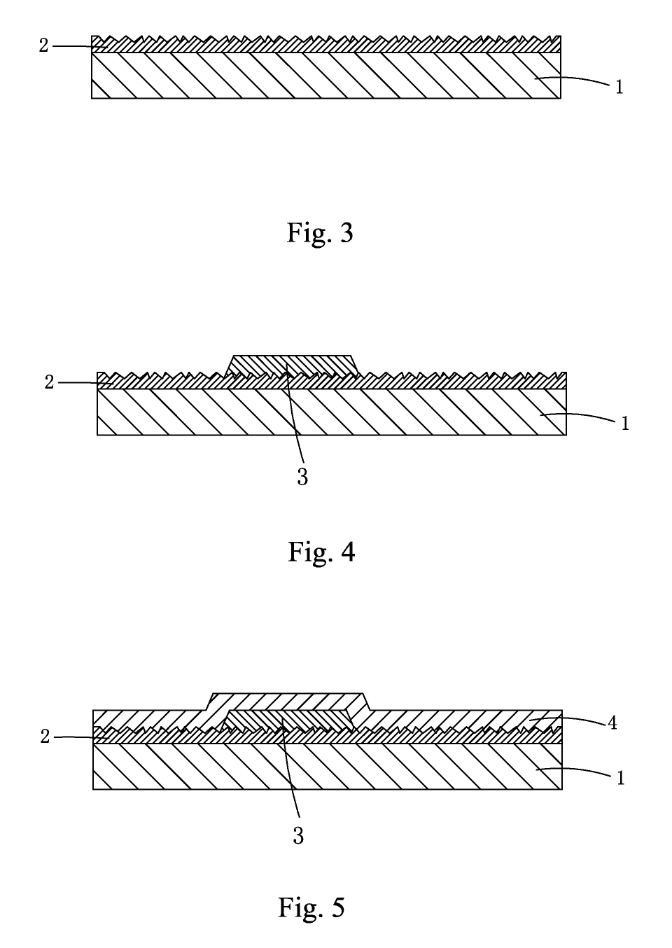

Step 1: as shown in FIG. 3, providing a substrate 1, depositing an inorganic film having a thinly distributed thin material on the substrate 1, and subjecting the inorganic film to a plasma bombardment treatment to have a surface thereof roughened to form a gate reflection prevention layer 2.

Specifically, the substrate 1 of Step 1 is preferably a glass substrate; the inorganic film is formed of a material of silicon dioxide (SiO₂) and has a thickness of 1000-3000 Å; and the plasma bombardment treatment uses a gas of nitrogen (N₂), oxygen (O₂), or nitrogen dioxide (NO₂).

Step 2: as shown in FIG. 4, depositing a first metal layer on the gate reflection prevention layer 2 and patterning the first metal layer to form a gate electrode 3.

Specifically, the first metal layer of Step 2 is formed of a material of one of chromium (Cr), molybdenum (Mo), aluminum (Al), and copper (Cu) or a combination of multiple ones thereof and has a thickness of 1000-6000 Å; the patterning is achieved with operations of coating photoresist (PR), exposure, development, wet etching, and peeling off the photoresist.

Step 3: as shown in FIG. 5, depositing a gate insulation layer 4 on the gate electrode 3 and the gate reflection prevention layer 2.

Specifically, the gate insulation layer 4 of Step 3 is formed of a material of silicon oxide (SiOₓ), silicon nitride (SiNₓ), or a combination thereof and has a thickness of 2000-5000 Å.

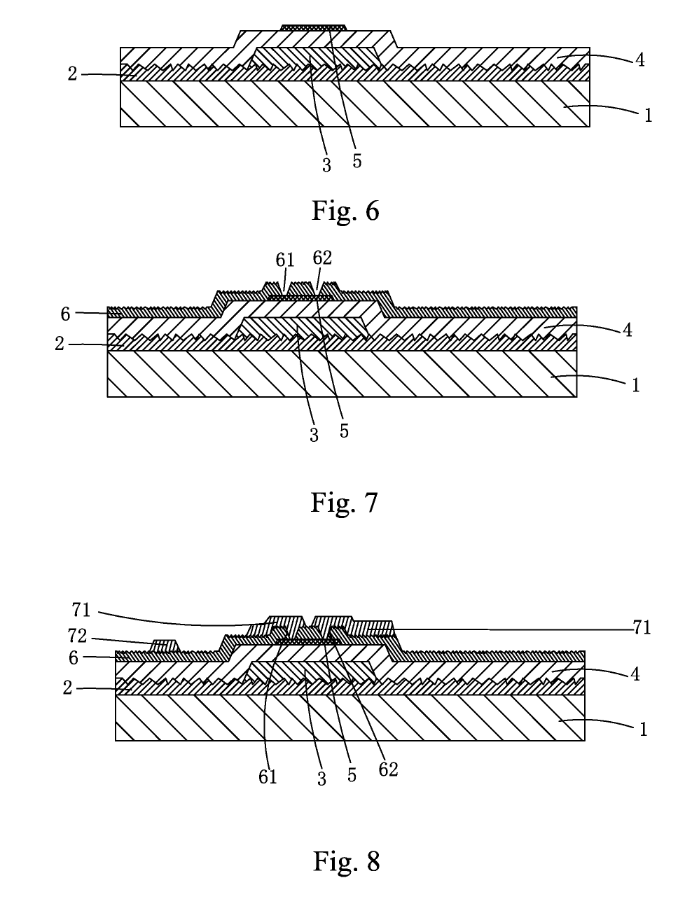

Step 4: as shown in FIG. 6, depositing a semiconductor film on the gate insulation layer 4 and patterning the semiconductor film to form an island-like active layer 5.

Specifically, the semiconductor film of Step 4 is formed of a material of one of zinc oxide (ZnO), indium zinc oxide (InZnO), zinc tin oxide (ZnSnO), gallium indium zinc oxide (GaInZnO), zirconium indium zinc oxide (ZrInZnO) and has a thickness of 200-2000 Å; the patterning is achieved with operations of coating photoresist, exposure, development, wet etching, and peeling off the photoresist.

Step 5: as shown in FIG. 7, depositing an inorganic film on the island-like active layer 5 and the gate insulation layer 4, subjecting the inorganic film to a plasma bombardment treatment to have a surface thereof roughened to form an etching stop and source/drain reflection prevention layer 6, and then patterning the etching stop and source/drain reflection prevention layer 6 to form a first via 61 and a second via 62,the first via and the second via respectively exposing two opposite side portions of the island-like active layer 5.

Specifically, the inorganic film of Step 5 is formed of a material of silicon oxide and has a thickness of 500-2000 Å; the plasma bombardment treatment uses a gas of nitrogen, oxygen, or nitrogen dioxide.

The patterning of the etching stop and source/drain reflection prevention layer 6 is achieved with operations of coating photoresist, exposure, development, dry etching, and peeling off the photoresist.

Step 6: as shown in FIG. 8, depositing a second metal layer on the etching stop and source/drain reflection prevention layer 6, and then patterning the second metal layer to form source/drain electrodes 71 and a data line 72, wherein the source/drain electrodes 71 are respectively connected by the first via 61 and the second via 62 to the island-like active layer 5.

Specifically, the second metal layer of Step 6 is formed of a material of one of chromium, molybdenum, aluminum, and copper or a combination of multiple ones thereof and has a thickness of 1000-6000 Å; the patterning is achieved with operations of coating photoresist, exposure, development, wet etching, and peeling off the photoresist.

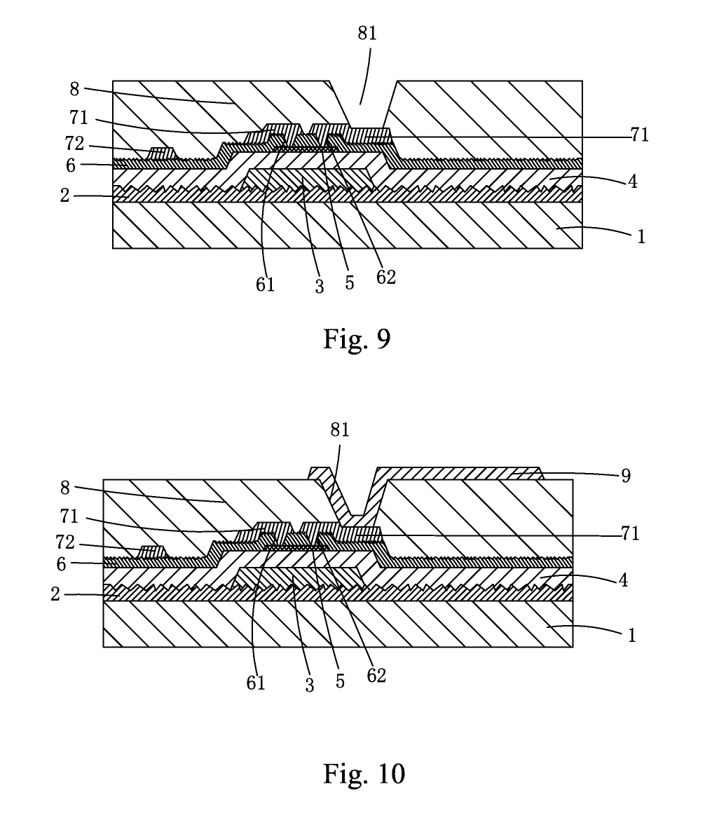

Step 7: as shown in FIG. 9, depositing a passivation protection layer 8 on the source/drain electrodes 71, the data line 72 the etching stop and source/drain reflection prevention layer 6, and then patterning the passivation protection layer 8 to form a third via 81, the third via exposing a portion of the source/drain electrodes 71.

Specifically, the passivation protection layer 8 of Step 7 is formed of a material of silicon oxide, silicon nitride, or a combination thereof and has a thickness of 2000-4000 Å; the patterning is achieved with operations of coating photoresist, exposure, development, dry etching, and peeling off the photoresist.

Step 8: as shown in FIG. 10, depositing a transparent electrode layer on the passivation protection layer 8 and patterning the transparent electrode layer to form a pixel electrode layer 9, wherein the pixel electrode layer 9 is connected by the third via 81 to a portion of the source/drain electrodes 71.

Specifically, the transparent electrode layer of Step 8 is formed of a material of indium tin oxide (ITO) or indium zinc oxide (IZO) and has a thickness of 100-1000 Å. The process of patterning the transparent electrode layer to form the pixel electrode layer 9 comprises the operations of coating photoresist, exposure, development, wet etching, and peeling off the photoresist.

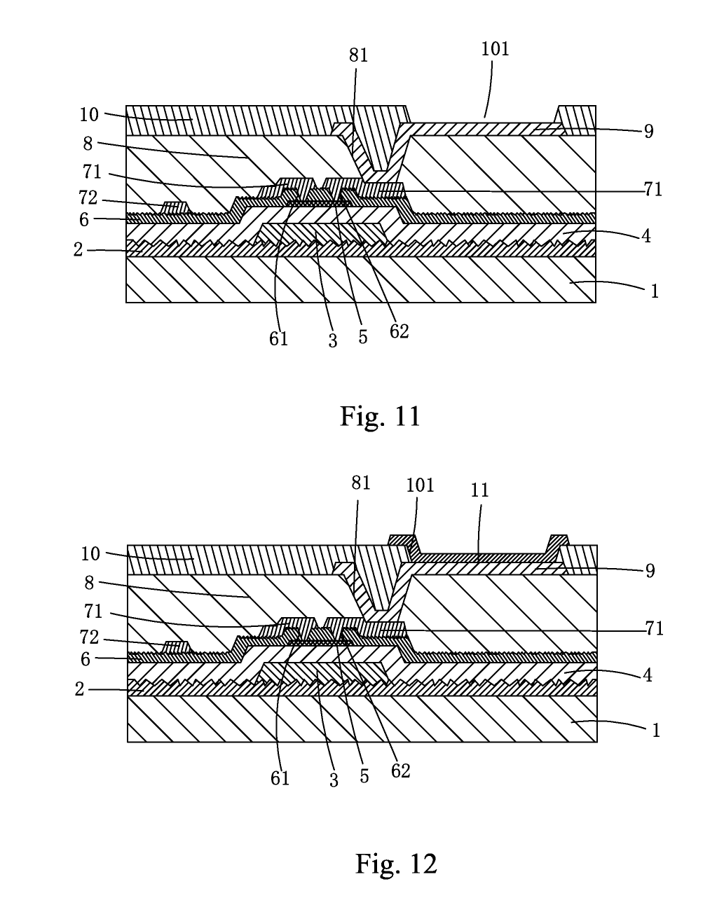

Step 9: as shown in FIG. 11, depositing a pixel separation layer 10 on the pixel electrode layer 9 and the passivation protection layer 8 and patterning the pixel separation layer 10 to form an opening 101 that exposes a portion of the pixel electrode layer 9.

Specifically, the pixel separation layer 10 of Step 9 is formed of a material of silicon oxide and has a thickness of 500-2000 Å; the patterning is achieved with operations of coating photoresist, exposure, development, wet etching, and peeling off the photoresist.

Step 10: as shown in FIG. 12, applying a vapor deposition operation to form an organic light emission layer 11 in the opening 101.

Specifically, the organic light emission layer 11 comprises a hole injection layer, a hole transport layer, an emissive layer, an electron transport layer, and an electron injection layer.

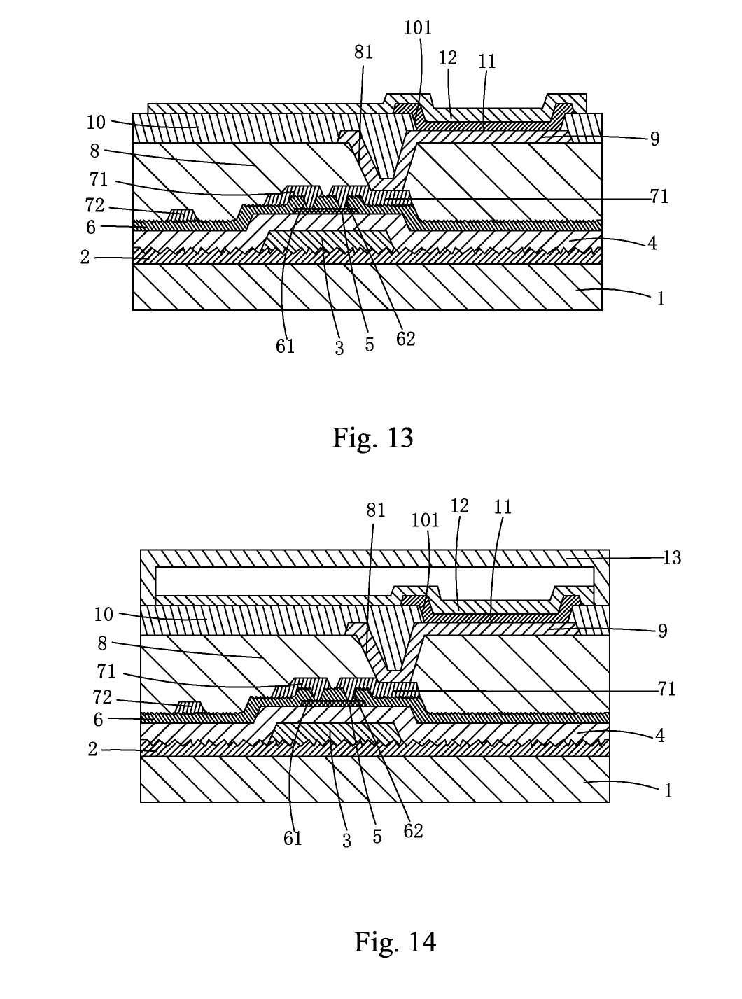

Step 11: as shown in FIG. 13, sputtering a metallic cathode layer 12 on the organic light emission layer 11 and the pixel separation layer 10.

Step 12: as shown in FIG. 14, packaging with a package lid 13.

The present invention provides a method for manufacturing an AMOLED display device, wherein a gate reflection prevention layer 2 and an etching stop and source/drain reflection prevention layer 6 are formed, both of which have a roughened surface that scatters light entering the AMOLED display device from an external environment so as to prevent the external surrounding light from being reflected by the gate electrode 3, the source/drain electrodes 71, the data line 72, the pixel electrode layer 9, and the metallic cathode layer 12, whereby the AMOLED display device may have increased display brightness and extended lifespan, a reduced thickness, and a lowered manufacturing cost.

On the basis of the above-described method for manufacturing an AMOLED display device, the present invention also provides a structure of an AMOLED display device, which as shown in FIG. 14, comprises an array substrate, and a passivation protection layer 8, a pixel electrode layer 9, a pixel separation layer 10, an organic light emission layer 11, a metallic cathode layer 12, and a package lid 13 that are arranged, in sequence from bottom to top, on the array substrate. The array substrate is provided with a gate metal reflection prevention layer 2, which has a roughened surface, located under a gate electrode 3 and an etching stop and source/drain reflection prevention layer 6, which has a roughened surface, located under source/drain electrodes 71 and a data line 72.

Specifically, the array substrate comprises a substrate 1, a gate reflection prevention layer 2 arranged on the substrate 1, a gate electrode 3 arranged on the gate reflection prevention layer 2,a gate insulation layer 4 arranged on the gate electrode 3 and the gate reflection prevention layer 2, an island-like active layer 5 arranged on the gate insulation layer 4 and located above the gate electrode 3, an etching stop and source/drain reflection prevention layer 6 arranged on the island-like active layer 5 and the gate insulation layer 4, and source/drain electrodes 71 and a data line 72 arranged on the etching stop and source/drain reflection prevention layer 6; the etching stop and source/drain reflection prevention layer 6 comprises a first via 61 and a second via 62 formed therein to respectively expose two opposite side portions of the island-like active layer 5; the source/drain electrodes 71 are respectively connected by the first via 61 and the second via 62 to the island-like active layer 5.

The passivation protection layer 8 is arranged on the source/drain electrodes 71, the data line 72, and the etching stop and source/drain reflection prevention layer 6 and comprises a third via 81 that expose a portion of the source/drain electrodes 71; the pixel electrode layer 9 is arranged on the passivation protection layer 8 and is connected by the third via 81 to a portion of the source/drain electrodes 71; the pixel separation layer 10 is arranged on the pixel electrode layer 9 and comprises an opening 101 that exposes a portion of the pixel electrode layer 9; the organic light emission layer 11 is arranged in the opening 101 of the pixel electrode layer 9; and the metallic cathode layer 12 is arranged on the organic light emission layer 11 and the pixel separation layer 10.

The gate metal reflection prevention layer 2 is formed of a material of silicon dioxide and has a thickness of 1000-3000 Å.

The etching stop and source/drain reflection prevention layer 6 is formed of a material of silicon oxide and has a thickness of 500-2000 Å.

The present invention provides an AMOLED display device, wherein a gate reflection prevention layer 2 and an etching stop and source/drain reflection prevention layer 6 are formed, both of which have a roughened surface that scatters light entering the AMOLED display device from an external environment so as to prevent the external surrounding light from being reflected by the gate electrode 3, the source/drain electrodes 71, the data line 72, the pixel electrode layer 9, and the metallic cathode layer 12, whereby the AMOLED display device may have increased display brightness and extended lifespan, a reduced thickness, and a lowered manufacturing cost.

In summary, the present invention provides a method for manufacturing an AMOLED display device, wherein before a gate electrode is formed, an inorganic film is first formed and the inorganic film is subjected to a plasma bombardment treatment to have a surface thereof roughened to form a gate reflection prevention layer and wherein before source/drain electrodes and a data line are formed, an inorganic film is first formed and the inorganic film is subjected to a plasma bombardment treatment to have a surface thereof roughened to form an etching stop and source/drain reflection prevention layer, whereby the AMOLED display device is provided with an excellent effect of preventing reflection of external surrounding light without adding a circular polarization sheet so as to increase the display brightness of the AMOLED display device, extend the lifespan of the AMOLED display device, and reduce the thickness and manufacturing cost of the AMOLED display device. The present invention provides a structure of an AMOLED display device, which comprises an array substrate that is provided with a surface-roughened gate metal reflection prevention layer located under a gate electrode and a surface-roughened etching stop and source/drain reflection prevention layer that is located under source/drain electrodes and a data line so as to have an excellent effect of preventing reflection of external surrounding light and have increased display brightness, extended lifespan, a reduced thickness, and a lowered manufacturing cost.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A method for manufacturing an active matrix organic light emitting diode (AMOLED) display device, comprising:
a step of first depositing an inorganic film before making a gate electrode, and then obtaining a rough surface of the inorganic film by a plasma bombardment treatment to form a gate reflection prevention layer; and
a step of first depositing an inorganic film before making source/drain electrodes and a data line, and then obtaining a rough surface of the inorganic film by a plasma bombardment treatment to form an etching stop and source/drain reflection prevention layer.

2. The method for manufacturing the AMOLED display device as claimed in claim 1 comprising the following steps:
(1) providing a substrate, depositing an inorganic film on the substrate, and subjecting the inorganic film to a plasma bombardment treatment to have a surface thereof roughened to form a gate reflection prevention layer;
(2) depositing a first metal layer on the gate reflection prevention layer and patterning the first metal layer to form a gate electrode;
(3) depositing a gate insulation layer on the gate electrode and the gate reflection prevention layer;
(4) depositing a semiconductor film on the gate insulation layer and patterning the semiconductor film to form an island-like active layer;
(5) depositing an inorganic film on the island-like active layer and the gate insulation layer, subjecting the inorganic film to a plasma bombardment treatment to have a surface thereof roughened to form an etching stop and source/drain reflection prevention layer, and then patterning the etching stop and source/drain reflection prevention layer to form a first via and a second via, the first via and the second via respectively exposing two opposite side portions of the island-like active layer;
(6) depositing a second metal layer on the etching stop and source/drain reflection prevention layer, and then patterning the second metal layer to form source/drain electrodes and a data line, wherein the source/drain electrodes are respectively connected by the first via and the second via to the island-like active layer;
(7) depositing a passivation protection layer on the source/drain electrodes, the data line, the etching stop and source/drain reflection prevention layer, and then patterning the passivation protection layer to form a third via, the third via exposing a portion of the source/drain electrodes;
(8) depositing a transparent electrode layer on the passivation protection layer, and then patterning the transparent electrode layer to form a pixel electrode layer, wherein the pixel electrode layer is connected by the third via to a portion of the source/drain electrodes;
(9) depositing a pixel separation layer on the pixel electrode layer and the passivation protection layer and patterning the pixel separation layer to form an opening that exposes a portion of the pixel electrode layer;
(10) applying a vapor deposition operation to form an organic light emission layer in the opening;
(11) sputtering a metallic cathode layer on the organic light emission layer and the pixel separation layer; and
(12) packaging with a package lid.

3. The method for manufacturing the AMOLED display device as claimed in claim 2, wherein the inorganic film of step (1) is formed of a material of silicon dioxide, and the inorganic film has a thickness of 1000-3000 Å.

4. The method for manufacturing the AMOLED display device as claimed in claim 2, wherein the inorganic film of step (5) is formed of a material of silicon oxide, and the inorganic film has a thickness of 500-2000 Å.

5. The method for manufacturing the AMOLED display device as claimed in claim 2, wherein the plasma bombardment treatments of step (1) and step (5) use a gas of nitrogen, oxygen, or nitrogen dioxide.

6. The method for manufacturing the AMOLED display device as claimed in claim 2, wherein the first metal layer of step (2) is formed of a material of one of chromium, molybdenum, aluminum, and copper or a combination of multiple ones thereof, and the first metal layer has a thickness of 1000-6000 Å;
the gate insulation layer of step (3) is formed of a material of silicon oxide, silicon nitride, or a combination thereof, and the gate insulation layer has a thickness of 2000-5000 Å;
the semiconductor film of step (4) is formed of a material of one of zinc oxide, indium zinc oxide, zinc tin oxide, gallium indium zinc oxide, and zirconium indium zinc oxide; and the semiconductor film has a thickness of 200-2000 Å;
the second metal layer of step (6) is formed of a material of one of chromium, molybdenum, aluminum, and copper or a combination of multiple ones thereof, and the second metal layer has a thickness of 1000-6000 Å;
the passivation protection layer of step (7) is formed of a material of silicon oxide, silicon nitride, or a combination thereof, and the passivation protection layer has a thickness of 2000-4000 Å;
the transparent electrode layer of step (8) is formed of a material of indium tin oxide or indium zinc oxide, and the transparent electrode layer has a thickness of 100-1000 Å;
the pixel separation layer of step (9) is formed of a material of silicon oxide, and the pixel separation layer has a thickness of 500-2000 Å; and
the organic light emission layer of step (10) comprises a hole injection layer, a hole transport layer, an emissive layer, an electron transport layer, and an electron injection layer.

7. A structure of an active matrix organic light emitting diode (AMOLED) display device, comprising an array substrate and a passivation protection layer, a pixel electrode layer, a pixel separation layer, an organic light emission layer, a metallic cathode layer, and a package lid that are arranged, in sequence from bottom to top, on the array substrate;
the array substrate comprising a gate metal reflection prevention layer that has a roughened surface, and the gate metal reflection prevention layer is arranged under a gate electrode; and
an etching stop and source/drain reflection prevention layer that has a roughened surface and is arranged under source/drain electrodes and a data line.

8. The structure of the AMOLED display device as claimed in claim 7, wherein the array substrate comprises a substrate, the gate reflection prevention layer arranged on the substrate, the gate electrode arranged on the gate reflection prevention layer, a gate insulation layer arranged on the gate electrode and the gate reflection prevention layer, an island-like active layer arranged on the gate insulation layer and located above the gate electrode, the etching stop and source/drain reflection prevention layer arranged on the island-like active layer and the gate insulation layer, and the source/drain electrodes and the data line arranged on the etching stop and source/drain reflection prevention layer; the etching stop and source/drain reflection prevention layer comprises a first via and a second via that respectively expose two opposite side portions of the island-like active layer; and the source/drain electrodes are respectively connected by the first via and the second via to the island-like active layer;
the passivation protection layer is arranged on the source/drain electrodes, the data line and the etching stop, and source/drain reflection prevention layer and comprises a third via, the third via exposing a portion of the source/drain electrodes;
the pixel electrode layer is arranged on the passivation protection layer and is connected by the third via to a portion of the source/drain electrodes;
the pixel separation layer is arranged on the pixel electrode layer and comprises an opening that exposes a portion of the pixel electrode layer;
the organic light emission layer is arranged in the opening of the pixel electrode layer; and
the metallic cathode layer is arranged on the organic light emission layer and the pixel separation layer.

9. The structure of the AMOLED display device as claimed in claim 8, wherein the gate metal reflection prevention layer is formed of a material of silicon dioxide, and the gate metal reflection prevention layer has a thickness of 1000-3000 Å.

10. The structure of the AMOLED display device as claimed in claim 8, wherein the etching stop and source/drain reflection prevention layer is formed of a material of silicon oxide and the etching stop and source/drain reflection prevention layer has a thickness of 500-2000 Å.

11. A structure of an active matrix organic light emitting diode (AMOLED) display device, comprising an array substrate and a passivation protection layer, a pixel electrode layer, a pixel separation layer, an organic light emission layer, a metallic cathode layer, and a package lid that are arranged, in sequence from bottom to top, on the array substrate;
the array substrate comprising a gate metal reflection prevention layer that has a roughened surface, and the gate metal reflection prevention layer is arranged under a gate electrode and an etching stop and source/drain reflection prevention layer that has a roughened surface and is arranged under source/drain electrodes and a data line;
wherein the array substrate comprises a substrate, the gate reflection prevention layer arranged on the substrate, the gate electrode arranged on the gate reflection prevention layer, a gate insulation layer arranged on the gate electrode and the gate reflection prevention layer, an island-like active layer arranged on the gate insulation layer and located above the gate electrode, the etching stop and source/drain reflection prevention layer arranged on the island-like active layer and the gate insulation layer, and the source/drain electrodes and the data line arranged on the etching stop and source/drain reflection prevention layer; the etching stop and source/drain reflection prevention layer comprises a first via and a second via that respectively expose two opposite side portions of the island-like active layer; and the source/drain electrodes are respectively connected by the first via and the second via to the island-like active layer;
the passivation protection layer is arranged on the source/drain electrodes, the data line and the etching stop, and source/drain reflection prevention layer and comprises a third via, the third via exposing a portion of the source/drain electrodes;
the pixel electrode layer is arranged on the passivation protection layer and is connected by the third via to a portion of the source/drain electrodes;
the pixel separation layer is arranged on the pixel electrode layer and comprises an opening that exposes a portion of the pixel electrode layer;
the organic light emission layer is arranged in the opening of the pixel electrode layer; and
the metallic cathode layer is arranged on the organic light emission layer and the pixel separation layer;
wherein the gate metal reflection prevention layer is formed of a material of silicon dioxide, and the gate metal reflection prevention layer has a thickness of 1000-3000 Å; and
wherein the etching stop and source/drain reflection prevention layer is formed of a material of silicon oxide, and the etching stop and source/drain reflection prevention layer has a thickness of 500-2000 Å.
